(19) United States
(12) Patent Application Publication
(10) Pub. No.: US 2009/0116526 A1
(43) Pub. Date: May 7, 2009

(54) Semiconductor light-emitting device with a surface emitting type

(76) Inventor: Jun-ichi Hashimoto, Yokohama-shi (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 12/076,532

(22) Filed: Mar. 19, 2008

(30) Foreign Application Priority Data
Mar. 26, 2007 (JP) 2007-079576

(51) Int. Cl. H01S 5/183; H01L 21/02

(52) U.S. Cl. 372/46.01; 438/46; 257/E21.002

(57) ABSTRACT

A structure of an optical device with the surface emitting type and a method to form the optical device are disclosed, where the optical device is able to operate in high frequencies. The device provides a lower DBR structure, an active layer, a current injection layer, a current blocking layer, and an upper DBR structure on a GaAs substrate. The current blocking layer, horizontally putting the current injection layer therebetween, are an un-doped GaInP grown at a temperature between 500 to 600° C. and an un-doped AlGaInP grown at a temperature between 500 to 650° C. Because the un-doped current blocking layer shows the high resistivity for both electrons and holes, the parasitic capacitance in the current blocking layer becomes small.

### CROSS-REFERENCE TO RELATED APPLICATIONS

The contents of the present application closely relates to applications, serial numbers of which are Ser. No. 11/889,613, filed Aug. 15, 2007, entitled by “Semiconductor laser diode with a mesa stripe buried by a current blocking layer made of un-doped semiconductor grown at a low temperature and a method for producing the same”, and Ser. No. 11/889,461, filed Aug. 13, 2007, entitled by “Semiconductor laser diode with a ridge structure buried by a current blocking layer made of un-doped semiconductor grown at a low temperature and a method for producing the same”, which are incorporated herein by reference in their entirely.

### BACKGROUND OF THE INVENTION

1. Field of the Invention

The present invention relates to a semiconductor optical device, in particular, the invention relates to a semiconductor laser diode with a vertical cavity surface emitting type.

2. Related Prior Art

A semiconductor laser diode with a type of vertical cavity surface emitting laser (hereinafter called as VCSEL) has been sought to apply in the field of the optical communication, the optical recording, the optical information processing and the like by utilizing their characteristics of a small-sized and low-powered device. The current blocking layer made of a group III-V compound semiconductor material has been well known in the VCSEL to confine the current injected thereto. A Japanese Patent Application published as JP-2005-243743A, or another Japanese Patent Application published as JP-H09-051145A, has disclosed a VCSEL with an iron (Fe) doped semiconductor layer for the current blocking layer.

Iron atoms doped in the semiconductor material operate as deep levels to trap free carriers. Accordingly, the Fe-doped semiconductor layer becomes a high resistive layer. However, irons do not show the trap function for holes; accordingly, it is inevitable to put an additional layer between the Fe-doped layer and the p-type layer, ordinarily the p-type cladding layer, to trap holes when the Fe-doped layer is applied to the current blocking layer in the laser diode, which increases the parasitic capacitance of the device, especially, between the cladding layer and the current blocking layer, and the high-frequency performance of the device is limited.

Moreover, since the Fe atoms show a relatively larger diffusion constant in the semiconductor material, the Fe atoms may easily inter-diffuse with a p-type dopant, typically zinc (Zn), by the thermal process of the crystal growth, the electrode formation and the like, when the p-type cladding layer is put on the Fe-doped layer. This inter-diffusion between Fe and Zn reduces the resistivity in the Fe-doped layer, while, the resistivity of the p-type layer is raised, which increases not only the leak current flowing in the blocking layer to lower the emission efficiency but the parasitic capacitance thereat to limit the high frequency performance of the device.

Thus, the present invention is to provide a VCSEL device able to operate in high frequencies by suppressing the increase of the parasitic capacitance in the current blocking layer.

### SUMMARY OF THE INVENTION

One aspect of the present invention relates to a structure of a vertical cavity surface emitting layer diode (VCSEL). This VCSEL comprises, on a GaAs substrate, a first DBR structure, an active layer, a second DBR structure, a current injection layer, a second DBR structure and a current blocking layer. The active layer, the current injection layer and the current blocking layer are vertically put between the first and second DBR structures, and the current blocking layer put the current injection layer therebetween. In the VCSEL of the present invention, the current blocking layer is one of an un-doped GaInP and an un-doped AlGaInP and horizontally put the current injection layer therebetween.

Because the current blocking layer of the invention comprises the un-doped GaInP or the un-doped AlGaInP showing the high-resistivity for both electrons and holes, the additional layer to show the high resistivity for the hole, which is inevitable in a case where the current blocking layer is made of Fe-doped material, becomes unnecessary, thus the parasitic capacitance does not increase and the high frequency performance of the device does not saturate. In addition, the un-doped GaInP or the un-doped AlGaInP applied to the current blocking layer enhances the designing flexibility of the device, in particular the designing of the current confinement structure of the VCSEL, because those materials may trap both types of carriers. Still further, the un-doped material does not cause the inter-diffusion of impurities between neighbor layers, which does not degrade the performance of the device, specifically, the emission efficiency and the high frequency performance.

Another aspect of the present invention relates to a method for manufacturing the VCSEL. The method may comprise steps of: (a) growing a first DBR structure, an active layer, and a semiconductor layer for a current injection layer in this order on a GaAs substrate; (b) etching the semiconductor layer so as to form a mesa structure of the current injection layer; (c) growing current blocking layer on both sides of the mesa structure of the current injection layer; and (d) forming a second DBR structure on the mesa structure of the current injection layer and the current blocking layer. In the present process, the current blocking layer may be a group of an un-doped GaInP grown at a temperature between 500 to 600° C. and an un-doped AlGaInP grown at a temperature between 500 to 650° C.

Because the un-doped GaInP or the AlGaInP of the current blocking layer is grown at a low temperature between 500 to 600° C., or between 500 to 650° C., these layers may contain deep levels to trap both electrons and holes, an additional layer to trap holes becomes unnecessary which increases the flexibility of the device design, specifically, the design of the layer configuration of the device.

One modification of the method above may comprise steps of: (a) growing a first DBR structure, an active layer, a blocking layer in this order on a GaAs substrate with a first conduction type; (b) diffusing impurities for a second conduction type into the current blocking layer form an opening of a dielectric film formed on the current blocking layer, the diffuse impurities converting a portion of the current blocking layer into a current injection layer with a second conduction type; and (c) growing a second DBR structure on the current blocking layer and the current injection layer after removing the dielectric film on the current blocking layer. Also in this modified process, the current blocking layer may be an un-doped GaInP grown at a temperature between 500 to 600° C. and an un-doped AlGaInP grown at a temperature between 500 to 650° C.

### BRIEF DESCRIPTION OF DRAWINGS

FIG. 1 schematically illustrates a cross section of an optical device with the surface emitting type according to the first embodiment of the invention;

FIG. 2 schematically illustrates a cross section of a specimen to investigate the resistivity of un-doped GaInP grown at a low temperature;

FIGS. 3A and 3B illustrate a relation of the resistivity of the un-doped GaInP grown at 500° C. and 550° C., respectively, with respect to the applied bias;

FIGS. from 4A to 4F illustrate steps of the first process to form the optical device according to the first embodiment shown in FIG. 1;

FIGS. 5A and 5B illustrate processes subsequent to the process shown in FIG. 4F to form the optical device of the first embodiment;

FIGS. 6A to 6C illustrate steps of the second process to form the optical device according to the first embodiment shown in FIG. 1;

FIG. 7 schematically illustrates across section of an optical device with the surface emitting type according to the second embodiment of the invention;

FIG. 8 schematically illustrates a cross section of an optical device with the surface emitting type according to the third embodiment of the invention;

FIG. 9 schematically illustrates a cross section of an optical device with the surface emitting type according to the fourth embodiment of the invention;

FIGS. 10A to 10C explain steps of the first process to form the optical device according to the fourth embodiment;

FIGS. 11A to 11F explain steps of the second process to form the optical device according to the fourth embodiment;

FIG. 12 schematically illustrates a cross section of an optical device with the surface emitting type according to the fifth embodiment of the invention; and

FIG. 13 schematically illustrates a cross section of an optical device with the surface emitting type according to the sixth embodiment of the invention.

### DESCRIPTION OF PREFERRED EMBODIMENTS

Next, embodiments of the present invention will be described in detail. The same numerals or the same symbols in the drawings refer to the same elements without overlapping explanations.

### First Embodiment

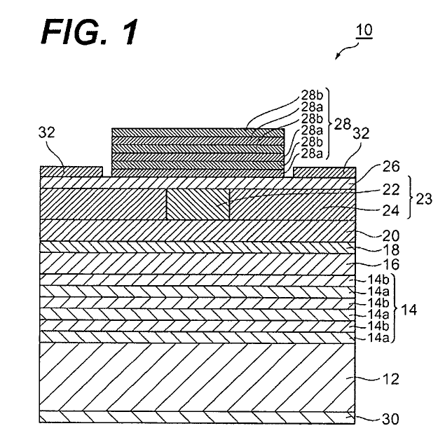

FIG. 1 is a cross section of an optical device with a type of the surface emitting according to the first embodiment of the invention. The surface emitting device 10 shown in FIG. 1 may be, for instance, a vertical cavity surface emitting laser diode (VCSEL), where the device 10 provides a first distributed Bragg Reflector (DBR) structure 14 with the first conductivity type on an n-type GaAs substrate 12, an active layer 18 provided on the first DBR structure 14, a current injecting layer 22 with a second conduction type, for instance the p-type, and provided on the first DBR structure to inject carriers into the active layer 18, a second DBR structure 28 provided on the current injecting layer 22, and a current blocking layer 28 provided between the first and second DBR structures, 14 and 28, respectively. This current blocking layer 24 is formed in the sides of the current injecting layer 22, and made of un-doped GaInP or un-doped AlGaInP. The current injecting layer 22 and the current blocking layer 24 form a current confinement structure 23 of the optical device 10.

The optical device 10 provides the current injecting layer 22 and the current blocking layer 24 between the active layer 18 and the second DBR structure 28. Specifically, the current injecting layer 22 is formed on a first area on the active layer 18, while, the current blocking layer 24 is provided in a second area surrounding the first area.

Between the first DBR structure 14 and the active layer 18 is formed with a spacer layer 16 with the first conduction type, while, the active layer 18 and the current confinement structure 23 put another spacer layer 20 with the second conduction type therebetween. These two space layers, 16 and 20, may confine the carriers within the active layer 18; however, the optical device 10 is not always necessary to provide these spacer layers. On the current confinement structure 23 and the second DBR structure 28 are provided with a contact layer 26 with the second conduction type, and an electrode 32 is formed on the contact layer 26. The second DBT structure 28 is in the first region on the contact layer 26, while the electrode 32 is formed on the second region surrounding the first region on the contact layer 26. The back surface of the GaAs substrate 12 provides another electrode 30.

The first DBR structure 14 includes a plurality of semiconductor layers, 14a and 14b, stacked alternately to each other. Thus, the first DBR structure 14 may have a multi-layered structure with two types of materials each having different refractive indices and being transparent in emission wavelengths of the optical device 10. Specifically, an n-type AlAs or an n-type AlGaAs, which constitutes the layer 14a, and an n-type GaAs of the layer 14b may form the first DBR structure 14 by stacking respective materials by 30 to 40 layers alternately. Such a multi-layered structure shows the reflectance over 99.9% for the emission wavelength of the device 10. Thicknesses of each layer, 14a and 14b, in the first DBR structure 14 may be λ/4/n, where n is an effective refractive index and λ is the emission wavelength, which is often called and the λ/4 film.

The first DBR structure 14 and the second DBR structure 28, both having the high reflectivity, define the optical cavity of the device 10. The light generated in the active layer 18 is multiply reflected within the cavity as being amplified therein to generate the coherent light. It is preferable that the total optical thickness, which is defined by the product of a physical thickness and an effective refractive index of a layer, summed by two spacer layers, 16 and 20, the active layer 18, the current injection layer 22 and the contact layer 26, becomes an integral multiplication of the emission wavelength λ. In other words, the optical device 10 selectively amplifies and emits the light with the wavelength thereof λ determined by the optical thickness within the cavity formed by two DBR structures, 14 and 28.

The active layer 18 may be made of group III-V compound semiconductor material including gallium (Ga), arsenic (As) and nitrogen (N), for instance, GaInNAs, GaNAs and the like, which realizes a light-emitting device with an emission wavelength in a region from 1.3 to 1.6 μm applicable to an optical communication system. The material for the active layer 18 is not restricted to those. Any material able to grow on the GaAs substrate may be applicable. The active layer is further preferable to be configured with a multiple-quantum well structure of un-doped GaInNAs well layers and un-doped GaAs barrier layers. The active layer may be a signal quantum well layer and may be also made of bulk structure.

The GaInNAs or GaNAs of the active layer 18 may be doped with one of antimony (Sb) or phosphorous (P). The former dopant, Sb, operates as a surfactant to suppress the three-dimensional growth of the GaInNAs or the GaNAs, which betters the crystal quality of the GaInNAs or the GaNAs. On the other hand, the latter dopant P contributes to better the crystal quality and the reliability of the device by relaxing the localized crystal stress, and to capture nitrogen atoms within the grown layer.

Alternatively, the active layer may be made of GaNAsP, GaInNAsP, GaNAsSb, GaInNAsSb, GaNAsSbP, GaInNAsSbP and the like. The lattice constant of these materials that contains gallium, nitrogen and arsenic, may be set substantially equal to or close to that of GaAs such that these materials are grown on the GaAs substrate. The bandgap energy of these materials is smaller than a value calculated from the bandgap wavelength of 1 μm, which corresponds to the peak wavelength of the photoluminescence spectrum of each material; accordingly, the active layer 18 made of those materials may realize an optical device applicable to a longer wavelength region over 1 μm, such as a VICSEL with the emission wavelength between 1.0 to 1.6 μm of the present invention.

The spacer layers, 16 and 20, are preferable to show a bandgap energy greater than that of the active layer 18, which effectively confines the carriers, the electrons and the holes, within the active layer 18. The space layers, 16 and 20, may be GaAs, AlGaAs, GaInAsP, GaInP, AlGaInP and the like which are able to be lattice matched with the GaAs substrate. However, the spacer layers, 16 and 20, may be unnecessary when the optical device 10 shows an excellent performance without the spacer layers, 16 and 20.

The current injection layer 22 may be made of materials applicable to the spacer layers, 16 and 20, but is preferable to have a bandgap energy greater than that of the spacer layer 20 not to reduce the carrier injection efficiency from the injection layer 22 to the active layer 18 without being interrupted by the hetero-barrier formed in the interface between the injection layer 22 and the spacer layer 20. We may optionally define the shapes and their dimensions of the current injection layer 22 across the stacking direction so as to obtain device performances.

The current blocking layer 24 may be preferably made of material with bandgap energy greater than that of the current injection layer 22 to form a hetero-barrier in an interface therebetween. Thus hetero-barrier enhances the carrier confinement efficiency within the current injection layer 22. A material involved in the group III-V compound semiconductor generally shows a smaller refractive index as the bandgap energy thereof becomes greater. Accordingly, the layer configuration of the embodiment, in which the current blocking layer 24 has the greater bandgap energy than that of the current injection layer 22, namely, the refractive index of the current injection layer 22 becomes larger than that of the current blocking layer 24, may effectively confine the light within a region contributory to the optical emission and enhance the efficiency of the stimulated emission in the active layer 18.

Specifically, the current blocking layer 24 of the embodiment may be made of un-doped GaInP or un-doped AlGaInP with bandgap energy, for instance, over 1.9 eV which is greater than that of GaAs, 1.4 eV, and shows a refractive index smaller than that of GaAs. The resistivity of un-doped GaInP or un-doped AlGaInP is preferably greater than 10⁵ Ωcm, by which the resistance of the current blocking layer 24 becomes greater than that of the current injection layer 22 by several digits; accordingly, nearly whole current may be confined in the current injection layer 22.

The contact layer 26 may be made of heavily doped GaAs and makes an ohmic contact with the electrode 32.

The second DBR structure 28 provides a plurality of layers, 28a and 28b, alternately stacked to each other on the contact layer 26. Each layer, 28a or 28b, is transparent for the emission wavelength of the device 10 and has refractive indices different from each other. Specifically, the second DBR structure 28 may be a combination of dielectric materials or a combination of semiconductor materials, for example, a combination of TiO₂ and SiO₂, or that of amorphous Si and SiO₂ is an example of the dielectric materials, and a combination of AlAs and GaAs, or AlGaAs and GaAs is an example of the semiconductor materials. When the second DBR structure is made of the combination of TiO₂ and SiOs, seven pairs of the combination are necessary to secure a high reflectivity. It is also preferable for the second DBR structure 28 to satisfy the λ/4 relation in its optical thickness to get a high reflectivity.

Unevenness in the top surface of the contact layer 26 makes it hard to grow the second DBR structure 28 with quality flatness, which results in the uncontrollable reflectivity of the second DBT structure 28. The device 10 of the present embodiment provides the current injection layer 22 and the current blocking layer 24 with a flat top surface, which forms the flat top surface of the contact layer 26. Thus, the reflectivity of the second DBR structure 28 becomes controllable and we may obtain the second DBR structure 28 with good homogeneity and good reproducibility.

The un-doped GaInP or the un-doped AlGaInP for the current blocking layer 24 may trap holes not only electrons, which makes a layer to trap the holes unnecessary. Generally, the layer to trap the holes is necessary to be heavily doped, which results in a larger junction capacitance. The present optical device 10, contrary to a conventional device with the hole-trapping layer, may reduce the junction capacitance, which enhances the high frequency performance of the device 10, for instance, over 10 GHz.

In addition, the un-doped GaInP or the un-doped AlGaInP of the current blocking layer 24 may operate as the trapping region in both sides of the n-conduction type and the p-conduction type, which enhances the flexibility of the layer configuration for the current confinement structure 23 constituted by the current injection layer 22 and the current blocking layer 24.

Moreover, in the conventional current blocking layer that dopes, for instance, iron (Fe) to increase the resistivity thereof, the dopant atoms are likely to inter-diffuse with doped atoms, for instance, zinc (Zn) in neighbor layers of the current injection layer, the contact layer, the spacer layer and the like. In this case, the current blocking layer diffused by dopant in the neighbor layers reduces its resistivity to increase the parasitic capacitance, while, the neighbor layer diffused with iron (Fe) increases its resistivity to block the current flowing thereat. These phenomena degrade the high-frequency performance of the device. On the other hand, the optical device 10 according to the present invention provides the current blocking layer 24 made of un-doped materials, accordingly; no inter-diffusion between the current blocking layer 24 and neighbor layers, 20, 22 and 26, may occur. Moreover, the no inter-diffusion makes the interface between the current injection layer 22 and the current blocking layer 24 abrupt, which easily controls the shape of the current injection layer 22, thus, enhances the homogeneity and the reproducibility of the device performances.

The present optical device 10 arranges the current injection layer 22 and the current blocking layer 24 between the active layer 18 and the second DBT structure 28, which does not degrade the crystal quality, accordingly the reflectivity, of the second DBR structure 28. Moreover, a closer arrangement between the current blocking layer 24 and the active layer 18 effectively suppresses the horizontal spreading of the current along the layer, the current being narrowed by the current injection layer 22 and the current blocking layer 24. The current spread horizontally becomes useless to the optical emission of the device 10.

The un-doped GaInP showing the high resistivity may be obtained by a low temperature growth below 600° C. Such a growth at a low temperature introduces deep levels within the energy bandgap. The un-doped AlGaInP with the high resistivity may be obtained by the similar low temperature growth below 650° C. The low temperature growth for AlGaInP also introduces the deep levels within the energy bandgap.

These deep levels operate as a capturing center to trap carriers, electrons and holes, to disturb the propagation of the carriers. Thus, the low temperature grown un-doped GaInP and un-doped AlGaInP show the quite high resistivity.

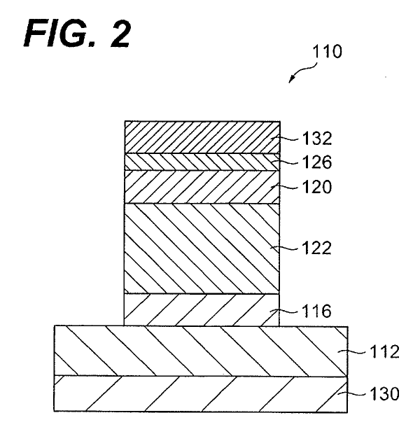

One experiment was carried out to verify the high resistivity of GaInP grown at a low temperature. FIG. 2 schematically illustrates a cross section of a specimen 110 used in the experiment. The specimen 110 has, provided on the n-type GaAs substrate 112, a pin structure constituted by an electron feeding layer 116, a high resistive layer 122, a hole feeding layer 120, and a contact layer formed on the substrate 110 in this order by, for instance, Organo-Metallic Vapor-Phase-Epitaxy (OMVPE) technique. The table below lists the configurations of respective layers:

TABLE
Layer configuration of the specimen

| | |
|---|---|
| electron feeding layer116 | n-type GaInP |
| | thickness: 0.5 μm |
| | [N]: 1 × 10¹⁷ cm⁻³, Si as dopant |
| high resistive layer 122 | undope-GaInP |
| | thickness: 1.5 μm |
| hole feeding layer 120 | p-type GaInP |
| | thickness: 0.5 μm |
| | [P]: 7 × 10¹⁷ cm⁻³, Zn as dopant |
| contact layer 126 | p-type GaAs |
| | thickness: 0.2 μm |
| | [P]: 1 × 10¹⁹ cm⁻³, Zn as dopant |

Two feeding layers, 116 and 120, provide carriers into the high resistive layer 122. The un-doped GaInP of the high-resistive layer is preferably grown between 500 and 600° C. After the growth of the layers, the stacked structure was shaped to a round mesa with a diameter of 200 μm. The contact layer 126 formed the anode electrode 132 thereon, while, the back surface of the GaAs substrate 112 formed the cathode electrode 130. The experiment measured the resistivity of the specimen thus prepared from the current-to-bias characteristic, the I-V characteristic.

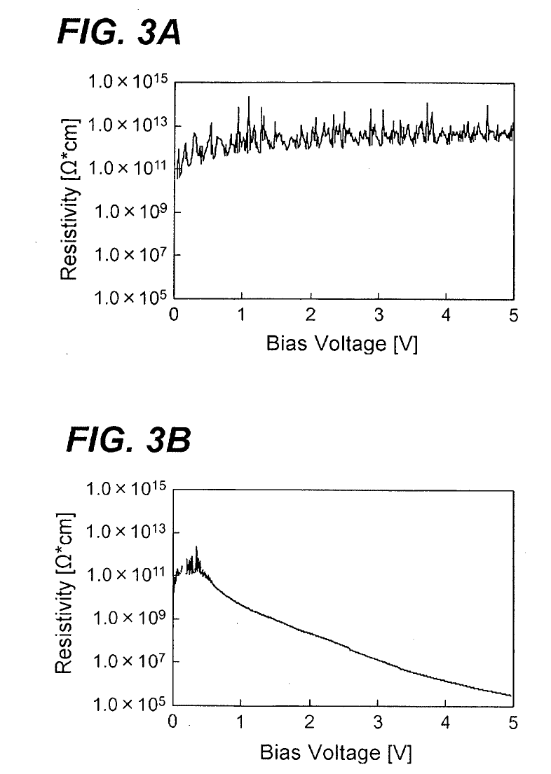

FIG. 3A illustrates the I-V characteristic of the specimen whose un-doped GaInP in the high resistive layer was grown at 500° C., while, FIG. 3B illustrates the I-V characteristic for the un-doped GaInP in the high resistive layer grown at 550° C. We may recognize that, in a bias range below 5V ordinary to the semiconductor laser, the specimen shows the resistivity greater than 10⁵ Ωcm, and the specimen, GaInP of which in the high resistive layer is grown at a lower temperature, shows higher resistivity. FIGS. 3A and 3B suggest that the un-doped GaInP grown at a low temperature forms many capture centers, and these centers trap both electrons and holes to show large resistivity for both carriers. When the traps in the un-doped GaInP capture only one type of carriers, then the un-doped GaInP shows a substantial conductivity due to the un-trapped carriers, and we could not obtain the high resistivity those shown in FIGS. 3A and 3B.

Thus, we can confirm that the un-doped GaInP grown at a low temperature plays a role of the high resistivity layer for both electrons and holes. The resistivity of the current injection layer 22 is around 0.2 Ωcm, which is far smaller than, more than six digits smaller, that of the un-doped GaInP which usually shows the resistivity over 10⁵ Ωcm. Therefore, the un-doped GaInP grown at a low temperature is applicable to the current blocking layer 24 of the semiconductor laser diode.

The un-doped AlGaInP grown at a low temperature may be also applicable to the current blocking layer. Because the un-doped AlGaInP contains aluminum (Al) that facilitates the formation of the deep levels, which equivalently means that the un-doped AlGaInP grown at higher temperature compared to that for the un-doped GaInP shows high resistivity. For instance, the un-doped AlGaInP grown at temperature higher than 600° C. shows enough resistivity. Generally, semiconductor crystals grown at higher temperatures tend to show good quality because the growth temperature becomes closer to the thermal equilibrium condition and the formation of the poly-crystal nucleus can be suppressed. The poly-crystal nucleus may be generated by a secondary reaction during the growth and deposited on the wafer as a residue to interfere the growth of the single Crystal. Thus, the un-doped AlGaInP may be superior to the un-doped GaInP in a viewpoint of the crystal quality. Moreover, we can adjust the bandgap energy of AlGaInP in a wide range by varying the aluminum composition, which enhances the flexibility of the current blocking layer 24. For instance, to increase the aluminum composition results in the enlargement of the bandgap energy and the decrease of the refractive index of the current blocking layer 24, which enhance the confinement of both the carriers and the light within the current injection layer 22.

Some VCSELs provide the current blocking layer doped with iron (Fe). The Fe performs the capturing center for electrons and such a semiconductor layer doped with Fe shows high resistivity for the electrons. However, because the iron atoms do not show a trap function for holes, we can not the materials doped with Fe as the current blocking layer against the p-type layer. The un-doped GaInP or the un-doped AlGaInP grown at a low temperature, because those materials shows the high resistivity with respect to both electrons and holes, may be applicable as the current blocking layer for both the n-type and the p-type semiconductor regions. Thus, the un-doped GaInP or the un-doped AlGaInP may not only enhance the design flexibility of the current blocking layer and the optical device as a whole compared to Fe-doped materials but also simplify the manufacturing process, in particular, the semiconductor layer growing process. The crystal growth without any doping procedure may omit the preparation procedure of the dopant, the facility to provide the dopant within the growth furnace, and the pre-experiment to determine the doping conditions.

The doped atom probably causes the inter-diffusion with the dopant in neighbor layers during the growth. It is well known that zinc (Zn), which is the dopant in the p-type cladding layer, easily inter-diffuses with iron in the current blocking layer. Such an inter-diffusion not only reduces the resistivity of the current blocking layer but also increases the parasitic capacitance of the current blocking layer to degrade the high-frequency performance of the device. The diffusion of the Fe into the p-type cladding layer increases the resistivity of the cladding layer. The un-doped semiconductor layer of the present embodiment does not bring any subjects mentioned above.

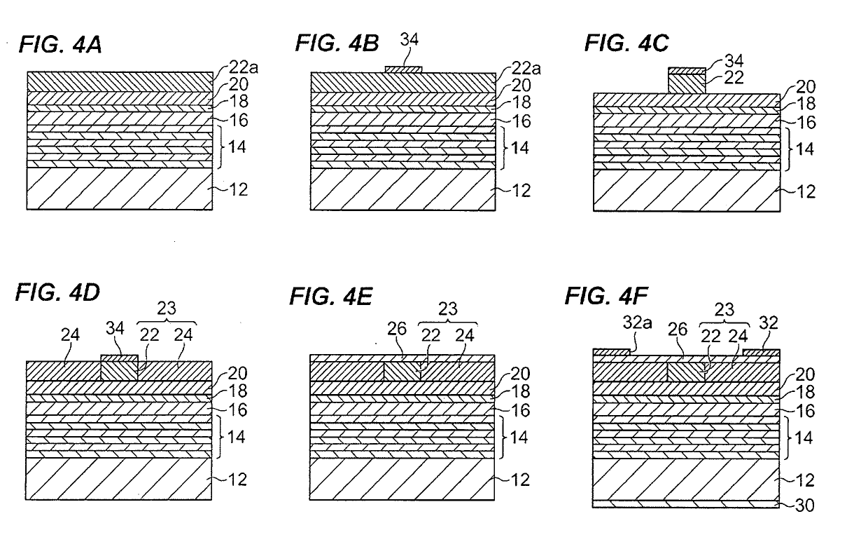

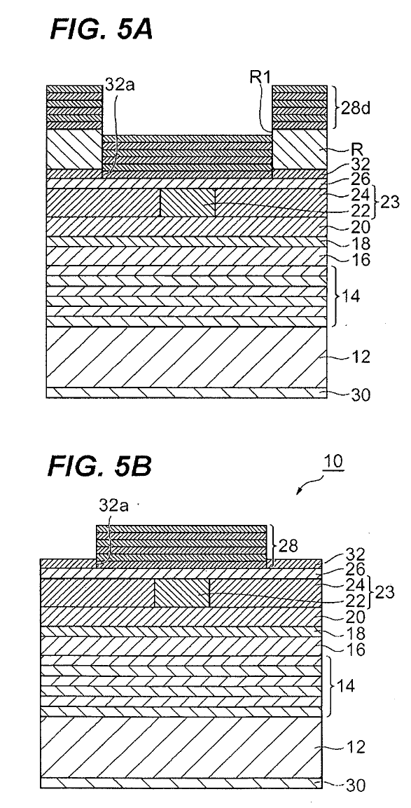

Next, a process to produce the optical device 10 with the surface emitting type will be described. FIGS. 4A to 4F and FIGS. 5A and 5B illustrate cross sections of the device at respective steps.

First, layers of the first DBR structure 14, the lower spacer layer 16, the active layer 18, the upper spacer layer 20 and the layer 22a for the current injection layer 22 are grown on the GaAs substrate 12 in this order by, for instance, the OMVPE technique, as shown in FIG. 4A.

Next, on the layer 22a is formed with the dielectric layer 34 with a predetermined pattern (FIG. 4B). The dielectric layer 34 may be, for instance, silicon nitride (SiN) or silicon oxide (SiO₂). The pattern may be optional, such as circular or rectangular.

Subsequently, the layer 22a is etched by the dielectric layer as an etching mask, which forms the current injection layer 22 with a mesa structure whose planar shape follows the predetermined pattern of the dielectric layer 34. An etchant containing hydrochloric acid (HCl) may be applicable to the etching when the upper spacer layer 20 is made of one of GaAs, AlGaAs or GaInAsP and the layer 22 is made of GaInP or AlGaInP. The etchant containing HCl shows an enough larger etching rate for GaInP or AlGaInP of the layer 22 compared to that for GaAs, AlGaAs, or GaInAsP so that the upper space layer 20 may have a function of the etching stopper layer. Even when the etching rate of the layer 22a varies within the wafer or batch to batch, we can obtain a good reproducibility and the homogeneity within the wafer with respect to the dimension of the current injection layer 22, the width and the height of the mesa, which results in the reproducibility and the homogeneity of the device.

In an modification, another etchant containing phosphoric acid may be applicable to a combination of the upper spacer layer made of GaInP or AlGaInP and the layer 22a of one of GaAs, AlGaAs or GaInAsP. Even in this case, the upper spacer layer 22a performs the etching stopper layer to give good reproducibility and homogeneity in the mesa shape of the current injection layer 22. However, the materials for the upper spacer layer 20 are not restricted to those mentioned above with a function of the etch-stopping. Even for those materials without etch-stopping function, optimized etching conditions may realize the good reproducibility and homogeneity.

The mesa shape of the current injection layer 22 may be optional, for example, a normal mesa and a reverse mesa with overhangs may be applicable to the current injection layer 22. This shape may be determined by the surface orientation of the layer 22a, the disposition of the dielectric layer 34 and the type of the etchant.

Next, the current blocking layer 24 is grown on the upper spacer layer 20, as shown in FIG. 4D, to form the current confinement structure 23. When the current blocking layer 24 is made of un-doped GaInP, the growth temperature of the un-doped GaInP is preferably lower than 650° C., further preferably between 500 to 550° C. When the current blocking layer 24 is made of un-doped AlGaInP, the growth temperature thereof is preferably below 650° C., more preferably between 500 to 550° C. Such a low-temperature growth for the un-doped GaInP or the un-doped AlGaInP may escape the active layer 18 from the thermal stress during the growth of the current blocking layer 24. For instance, compound semiconductor materials containing gallium (Ga), arsenic (As) and nitrogen (N), such as GaInNAs and the like, generally show a delicate characteristic against the thermal stress, accordingly, the current blocking layer made of un-doped GaInP or AlGaInP grown at a low temperature may be adequate for an active layer containing Ga, As and N. Although the growth of the current blocking layer 24 often follows a rough surface due to an abnormal growth in a vicinity of the dielectric pattern 34, an optimum shape of the dielectric pattern 34 and an idealized condition of the crystal growth may prevent such abnormal growth.

Next, as shown in FIGS. 4E and 4F, the process grows the contact layer 26 on the current injection layer 22 and the current blocking layer 24 after removing the dielectric pattern 34, and forms the electrode 32 on the contact layer 26 and the other electrode 30 on the back surface of the GaAs substrate 12. The former electrode 32 may provide an opening 32a not to block the light emitted from the active layer 18.

Lastly, as shown in FIGS. 5A and 5B, the process forms the second DBT structure 28 on the contact layer 26 by a procedure that a photo-resist pattern with an opening R1, which traces the opening 32a of the electrode 32, is firstly formed on the electrode 32, a stack of layers 28d for the second DBT structure 28 is formed so as to fill the opening R1 and on the resist pattern, and finally the resist pattern R is removed, which leaves the second DBT structure 28 only within the opening 32a of the electrode 32. The process mentioned above is, what is called as the lift-off process. Thus, the optical device 10 with the surface emitting type is completed.

When the un-doped AlGaInP is selected for the current blocking layer 24, we can obtain a quality crystal because the un-doped AlGaInP shows a high resistivity even grown at higher temperature than that from the un-doped GaInP. Moreover, when the current blocking layer 24 is made of un-doped AlGaInP while the current injection layer 22 is made of GaInP, this combination forms the hetero-barrier in the interface therebetween, because the AlGaInP 24 has bandgap energy wider than that of the GaInP, which enhances the carrier confinement within the GaInP thus improves the emission efficiency of the device. Moreover, because the AlGaInP has a smaller refractive index than the GaInP, the optical confinement within the current injection layer 22 may be enhanced, which raises the efficiency of the stimulated emission.

The optical device 10 according to the present embodiment provides the second DBR structure 28 independent of the current blocking layer 24, which solves problems appeared in a case where the current blocking layer is within the second DBR structure. Although such configuration may be formed by the two step growth of semiconductor layers, that is, the process first forms the lower portion of the second DBR structure 28, etches the grown portion of the second DBR structure 28 to form a hollow, grows the current blocking layer 24 within the hollow, and finally performs the second grown of the second DBR structure 28 on the lower portion thereof and on the current blocking layer 24. However, an interruption of the growth of the second DBR structure tends to bring a native oxide on the top surface thereof, which makes it difficult to secure the reflectivity of the second DBR structure 28 as designed. Moreover, the etching of the second DBR structure 28 tends to cause non-radiation centers on an un-evened surface formed by the etching, which may degrade the reliability of the device. In particular, because the second DBR structure 28 contains aluminum (Al) in a large amount, this layer is easily to be oxidized, which cases a large amount of the non-radiative centers. Moreover, the current blocking layer 24 is closer to the active layer 18 compared to conventional configurations where the current blocking layer is formed on the second DBR structure, which effectively reduces the useless current that derives from the current confined by blocking layer 24 spreading along the active layer 18.

FIGS. from 6A to 6C show processes of the optical device shown in FIG. 1 according to the second embodiment of the invention.

First, the process sequentially grows, on the GaAs substrate 12, the first DBR structure 14, the spacer layer 16, the active layer 18, the upper spacer layer 20, a high resistive layer 24a for the current blocking layer 24, and an un-doped layer 24 on the GaAs substrate 12 by, for instance, the OMVPE technique.

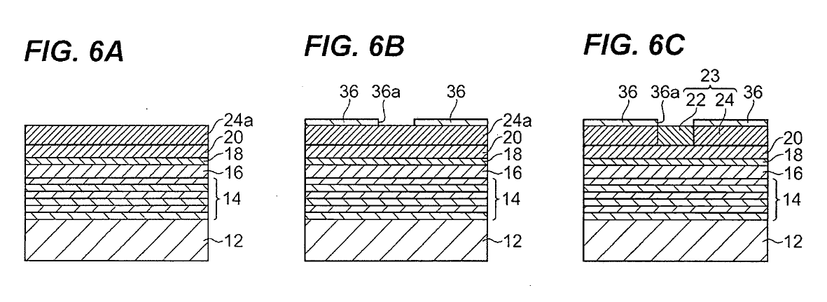

Next, on the high resistive layer 24a is formed with a dielectric film 36 with an aperture 36a, as shown in FIG. 6B. The dielectric film may be a silicon nitride (SiN) and a silicon die-oxide (SiO₂). The shape of the aperture 36a may be optional.

Next, the process dopes impurities with the second conduction type in an area of the high-resistive layer 24a exposed from the aperture 36a thereof. The thermal diffusion or the ion-implantation method may be applicable to the doping above. The former process, the thermal diffusion, is preferable from a viewpoint of the damage reduction of the doped layer because the ion implantation introduces defects in the semiconductor layer due to the collision of the accelerated ions by the field over several hundreds volts with lattice atoms. By this doping, the process forms the current injection layer 22 with relatively low resistivity in a region diffused by the dopant atoms, and, at the same time, the current confinement structure 23 with the current injection layer 22 and the current blocking layer 24 with high resistivity.

After removing the dielectric film 36, the same processes shown in FIGS. 4E, 4F, 5A and 5B are preformed, thus, the optical device 10 with the surface emitting type may be completed.

The first process potentially causes an un-evenness on the top surface of the current blocking layer 24 due to an abnormally grows at a vicinity of an edge of the dielectric film, which makes it hard to secure the flatness of the second DBR structure 28 on the current blocking layer 24. The un-evened layers within the second DBR structure 28 results in the in-homogeneity and the less reproducibility of the device.

On the other hand, the latter process, the thermal diffusion of doped impurities, carries no crystal growth with the patterned dielectric film 36 and does not cause the un-evenness of the top surface due to the abnormally growth. Thus, the second DBR structure 28 may be provided on the smooth surface of the current confinement structure 23. Moreover, the second process performs the onetime crystal growth because it omits the independent growth of the current blocking layer 24, which may improve the productivity of the device and reduce the cost thereof.

The doping of the impurities with the second conduction type according to the second process, the impurities may diffuse out from the doped region, which makes it hard to control the shape of the doping region. In the present optical device, this out-diffusion of impurities is hard to occur because the doped region is a type of the un-doped layer without any intentionally doped impurities. Comparing to a case where the current blocking layer is doped with iron (Fe) to secure the high-resistivity, the inter-diffusion of the doped impurities with the second conduction type to the current blocking layer may be reduced. The shape of the current injection layer, in particular, the shape of a region with a function of the current injection may be roughly determined by the shape of the doped region, which effectively secures the homogeneity and the reproducibility of the device.

### Second Embodiment

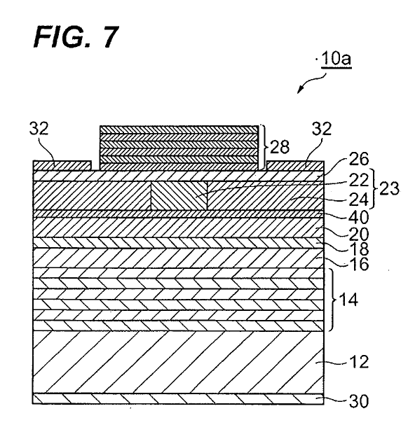

FIG. 7 is a cross section of an optical device with the surface emitting type according to a second embodiment of the invention. The optical device 10a shown in FIG. 7 provides, in addition to the layer configuration the optical device 10 in the first embodiment, an intermediate layer 40 with the second conduction type between the current confinement structure 23 and the upper spacer layer 20. This intermediate layer 40 may be made of GaAs, AlGaAs, or GaInAsP.

The process to form the optical device 10a will be described.

First, the process grows a series of semiconductor layers of the first DBR structure 14, the space layer 16, the active layer 18, the upper spacer layer 20, the intermediate layer 40 and the current injection layer 22a on the GaAs substrate 12 in this order. The OMVPE technique may also carry out the growth.

Next, the dielectric film 34 is formed on the current injection layer 22a.

Similar to the process shown in FIG. 4C, the process etches the current injection layer 22a with the dielectric film 34 as an etching mask. An etchant containing hydrochloric acid (HCl) may be applicable to the etching when the spacer layer 20 and the current injection layer 22a are made of GaInP or AlGaInP and, at the same time, the intermediate layer is made of GaAs, AlGaAs, or GaInAsP. In this case the intermediate layer 40 operates as an etching stopper layer, which brings good homogeneity and good reproducibility of the height and the width of the mesa of the current injection layer 22 even the etch rate for the current injection layer 22a scatters in the wafer or in batch to batch of the etching.

Subsequently, the processes same as those shown in FIGS. 4D to 4F, 5A and 5B are carried out to complete the optical device 10a.

When the spacer layer 20 and the current injection layer 22a are made of GaAs, AlGaAs or GaInP, the intermediate layer is preferable to be made of GaInP or AlGaInP. In this case, an etchant containing phosphoric acid may carry out the etching of the current injection layer 22a by the intermediate layer 40 as the etching stopper layer.

As described above, the intermediate layer 40 may function as the etching stopper layer for the etching of the current injection layer 22, where the mesa shape of the current injection layer 22 may be obtained with good homogeneity and reproducibility within the wafer.

### Third Embodiment

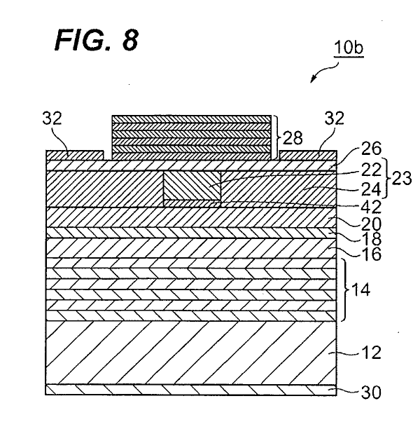

FIG. 8 is a cross section of an optical device with the surface emitting type according to the third embodiment of the invention. The optical device 10b shown in FIG. 8 provides, in addition to those appeared in the optical device 10 of the first embodiment, an intermediated layer 42 with the second conduction type only between the current injection layer 22 and the upper spacer layer 20. This intermediate layer 42 may be made of the same material with the intermediate layer 40 in the second embodiment. The optical device shown in FIG. 8 does not provide the intermediate layer 42 between the current blocking layer 24 and the upper spacer layer 20.

Because the intermediate layer 42 exists only between the current injection layer 22 and the spacer layer 20, it is possible by adjusting a characteristic of this intermediate layer 42 to improve the performance of the optical device 10b. The intermediate layer 42 may be made of semiconductor material whose refractive index is greater than that of the current blocking layer 24. Specifically, the intermediate layer 42 may be made of GaAs whose refractive index is grater than that of the current blocking layer 24 made of GaInP or AlGaInP. In this arrangement, an effective refractive index of a center region including the current injection layer 22 and the intermediate layer 42 becomes higher than regions existing both sides thereof and containing the current blocking layer 24, the light may be more strongly confined within the center region, which improves the performance of the device 10b.

A method to manufacture the optical device 10b according to the third embodiment will be described. First, a process similar to that for the device 10a of the prior embodiment forms the dielectric film 34 on the current injection layer 22a. Subsequently, the current injection layer 22 and the intermediate layer 42 may be obtained by etching the layer 22a and the layer 40. When the spacer layer 20 and the layer 22a are made of GaInP or AlGaInP, at the same time, the layer 40 is made of GaAs, AlGaAs, or GaInAsP, an etchant containing hydrochloric acid (HCL) is applicable to the etch layer 22a. While, another solution containing a phosphoric acid is used to etch the layer 40. The layer 40 may perform an etching stopper layer for the etching of the layer 22a, and the spacer layer 20 performs a roll of the etching stopper layer for the etching of the spacer layer 20. Thus, good homogeneity and good reproducibility may be secured with respect to the mesa shape of the current injection layer 22 and the intermediate layer 42.

Subsequently, the processes same as those shown in FIGS. 4D to 4F, 5A and 5B are carried out to complete the optical device 10a.

On the other hand, when the spacer layer 20 and the layer 22a are made of GaAs, AlGaAs or GaInAsP, the intermediate layer 40 is preferably made of GaInP or AlGaInP. In this case, the solution containing phosphoric acid may be preferable for the etching of the layer 22a, while, the solution containing the hydrochloric acid may be applicable to the etching of the layer 40. Because the space layer 20 and the intermediate layer 40 performs a function of the etching stopper, the good homogeneity and the good reproducibility may be obtained also in this case.

### Fourth Embodiment

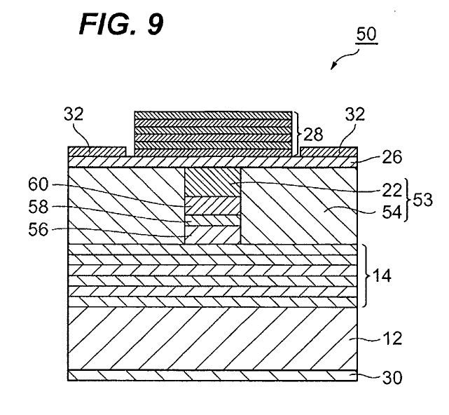

FIG. 9 is a cross section of an optical device with the surface emitting type according to the fourth embodiment of the invention. The optical device 50 shown in FIG. 9 provides, in the arrangement of the optical device 10, a spacer layer 56, an active layer 58, an upper spacer layer 60 and a current blocking layer 54, instead of the upper and lower spacer layers, 16 and 20, the active layer 18 and the current blocking layer 24 but materials thereof are same with those in the former device 10. The former three layers, 56 to 60, each have a mesa shape. The current injection layer 22 and the current blocking layer 54 forms the current confinement structure 53. The current blocking layer 54 covers the sides of the spacer layers, 56 and 60, and the side of the active layer 58, and the side of the current injection layer 22.

The optical device 50 brings the same functions and the effects with those appeared and explained in the former embodiments. Moreover, the device 50 provides the current blocking layer 54 covers the sides of the active layer 58, which strengthens the current confinement within the active layer 58 and effectively reduces the useless current spreading along the layer extension. Moreover, the refractive index of the current blocking layer, when the blocking layer 54 is made of GaInP or AlGaInP, is generally smaller than that of the active layer 58, which effectively confines the light within the active layer 58. Thus, the optical device 50 effectively confines both the current and the photon in the active layer 58, which makes it possible to get an optical device with high efficiency accordingly, the low threshold current. Furthermore, the arrangement according to the present embodiment is possible to thicken the current blocking layer 54, which reduces the parasitic capacitance attributed to the current blocking layer 54, thus, makes it possible to get an optical device with the surface emitting type operable in higher frequency regions.

The previously optical devices, 10 to 10b, tend to show a behavior that a portion of carriers injected from the electrodes, 30 and 32, diffuse along the layer extension at the spacer layers, 16 and 20, and the active layer 18 to become an useless current that makes no contribution to the laser emission. While, the device 50 according to the present embodiment effectively confines the carrier injected from the electrodes, 30 and 32, within the active layer put between the current blocking layer 54. Thus, the device 50 may effectively reduce the useless current.

Moreover, the optical device 50 of the present embodiment has a layer configuration that the current blocking layer 54 made of GaInP or AlGaInP exits in both sides of the active layer 58 and those materials generally has a refractive index smaller than that of the active layer 58, which strengthens the confinement of the light within the active layer due to the difference of the refractive index of layers compared to the devices, 10 to 10b, in former embodiments where the current blocking layer 18 and the spacer layers, 16 and 20, locates on or below the active layer without no difference of the refractive index horizontally. Accordingly, the efficiency to cause the stimulated emission is increased, which realizes the optical device with low threshold current and high emission efficiency.

The optical device 50 according to the present embodiment may provide the current blocking layer 54 thicker than those provided in the former optical devices, 10 to 10b, which may reduce the parasitic capacitance thereat and may consequently improve the high frequency performance of the device 50.

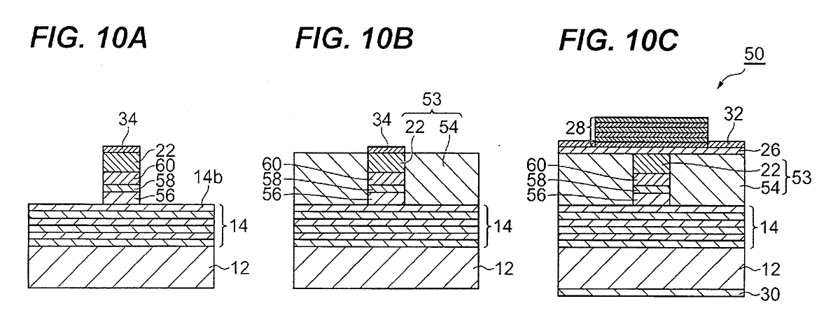

FIGS. from 10A to 10C illustrate processes to produce the optical device 50 of the fourth embodiment. First, subsequent to the first growth of layers same as those appeared in the first to third embodiments, the dielectric film 34 is formed on the layer 22a. Next, as shown in FIG. 10A, the process etches the layer 22a, the upper spacer layer 20, the active layer 18 and the lower spacer layer 16 by the dielectric film 34 as the etching mask, which forms a mesa including the current injection layer 22, the upper spacer layer 60, the active layer 58 and the lower spacer layer 56.

The wet-etching may be applicable to form the mesa above. As mentioned, when the layers, 16, 20 and 22a, are made of GaInP or AlGaInP, the solution containing the hydrochloric acid may etch the layers, 16, 20 and 22a, while, when the active layer 18 is made of a combination of GaInNAs and GaAs, the phosphoric acid may etch this active layer easily. The topmost layer of the first DBR structure 14, which is the layer 14b in this embodiment, however, the layer 14a may be the topmost layer of the first DBR structure 14 depending on the stacking sequence thereof, is preferably made of material not containing aluminum (Al), that is, the topmost layer of the first DBR structure 14 is preferably GaAs not AlAs, because the etching exposes the AlAs layer beneath the lower spacer layer 16 and the aluminum contained therein is easily oxidized to cause a lot of defects to make it hard to re-grow the semiconductor layer on this AlAs layer. When the GaAs is the topmost layer of the first DBR structure 14, the GaAs may perform the function of the etch-stopper layer for the etchant containing hydrochloric acid, which results in the good homogeneity and the good reproducibility with respect to the mesa shape; accordingly, to the performance of the optical device 50.

Next, the process grows the current blocking layer 54 on the first DBR structure 14 so as to form the current confinement structure 53 by burying the mesa. As described, when the current blocking layer 54 is made of un-doped GaInP, the process preferably set the growth temperature below 600° C., more preferably between 500 to 550° C. While, the current blocking layer is made of un-doped AlGaInP, the growth temperature of this layer is preferably below 650° C., more preferably between 500 to 550° C. The low temperature grown of this current blocking layer 54 may escape the active layer 58 from the thermal stress during the growth of the blocking layer 54. Specifically, because a group III-V compound semiconductor material containing gallium (Ga), arsenic (As) and nitrogen (N), such as GaInNAs, shows a less resistance against the thermal stress, the current blocking layer 54 grown at a low temperature is quite preferably for the active layer made of such semiconductor materials.

After the second growth for the current blocking layer 54, the processes same as those shown in FIGS. 4E, 4F, 5A and 5B may complete the optical device whose cross section is illustrated in FIG. 10C.

In the first process mentioned above, the first DBR structure, in particular, an upper portion thereof is possibly etched so as to expose it. As mentioned earlier, when the first DBR structure 14 contains aluminum (Al) in the topmost layer thereof, the exposed surface of the topmost layer, namely, the interface between the first DBR structure and the current blocking layer, may often generate defects derived from the oxidization of aluminum.

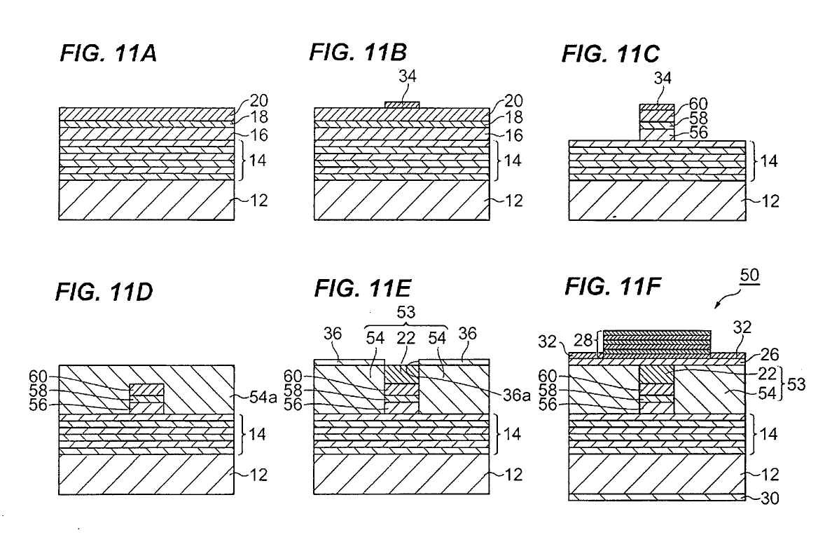

A modified process that escapes the re-grown current blocking layer 54 from growing abnormally closer to the dielectric film 34 will be shown. FIGS. from 11A to 11F illustrate processes to form the optical device according to the fourth embodiment. First, a stack of layers, the first DBR structure 14, the spacer layer 16, the active layer 18 and the other space layer 20, is grown on the GaAs substrate by the OMVPE method, and the dielectric film 34 is subsequently formed on the stack, as shown in FIG. 11B.

The mesa including layers, 60, 58, and 56 are formed by the etching of those layers with the dielectric film 34 as the etching mask. Next, the un-doped layer 54a grown at a low temperature is formed on the first DBR structure 14 so as to cover the upper spacer layer 60, the active layer 58 and the lower spacer layer 56 after removing the first dielectric film 34.

Next, the process forms on the layer 54a another dielectric film 36 with an opening 36a to expose the top of the mesa. As shown in FIG. 11E, a portion of the layer 54 exposing from the opening 36a is doped with impurities with the second conduction type, specifically, zinc (Zn) is applicable for the p-type dopant. This doping may be carried out by the thermal diffusion or the ion-implantation. The doped portion of the layer 54a becomes the current injection layer 22, while the rest portion of the layer 54a covered by the dielectric film 56 and not doped with impurities becomes the current blocking layer 54. Thus, the process converts the layer 54a into the current injection layer 22 and the current blocking layer 54 to form the current confinement structure 53. The processes shown in FIGS. 4E, 4F, 5A and 5B, subsequent to remove the dielectric film 36 complete the optical device shown in FIG. 11F.

The first process for the optical device according to the fourth embodiment possibly brings the uneven top surface of the current blocking layer 54 due to the abnormal growth in a region vicinity of the dielectric film 34, which makes it difficult to get the flatness of the second DBR structure on the current blocking layer 54; accordingly, not only reflectivity thereof but the homogeneity and the reproducibility of the second DBR structure 28 are improved.

However, the second method for the optical device 50 explained above, the second growth of semiconductor layer does not use the dielectric film; accordingly, the uneven top surface due to the abnormal growth does not occur. We can form the second DBR structure 28 on the current confinement structure 53 with the flat surface.

Generally, the doping method applied to the second process for the optical device 50 has a difficulty to control the dimensions of the doped region due to the inter-diffusion of the impurities. The present layer configuration of the device 50 provides the un-doped layer 54a to be doped by the impurities, the inter-diffusion above is hard to occur. Accordingly, the shape or the dimensions of the current injection region almost follows the dimensions of the doped region, which may also effectively enhance the homogeneity and the reproducibility of the device 50.

### Fifth Embodiment

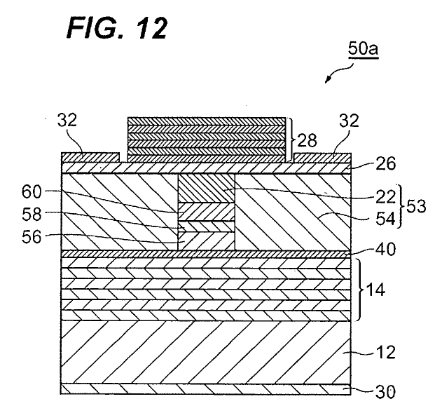

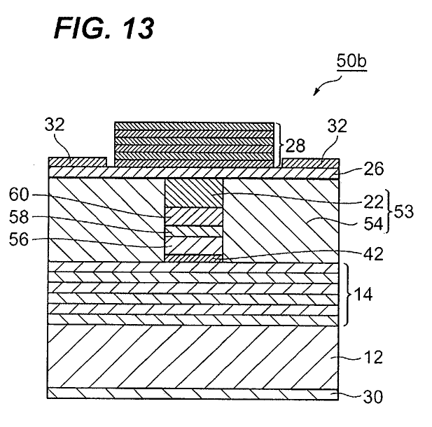

FIG. 12 schematically shows a cross section of an optical device with the surface emitting type according to the fifth embodiment of the invention. The optical device 50a shown in FIG. 12 provides, in addition to the configuration of the device 50, an intermediate layer 40 set between the current confinement structure 53 and the first DBR structure 14, and between the current blocking layer 54 and the first DBR structure 14. The device 50a shows functions and performances similar to, or same with those appeared and explained in the former embodiments.

Next, a method to manufacture the device 50a will be described.

First, a stack of layers, 14, 40, 16, 18, 20 and 22a, is grown on the GaAs substrate 12 in this order as illustrated in FIG. 4A. Subsequently, the process forms the dielectric film 34 on the layer 22a, as shown in FIG. 4B. Similar to the process shown in FIG. 10A, the grown layers are etched so as to shape a mesa, which forms the current injection layer 22, the upper spacer layer 60, the active layer 58 and the lower spacer layer 56.

The wet-etching may be applicable to form the mesa above. As mentioned, when the layer 22a is made of GaInP or AlGaInP, the solution containing the hydrochloric acid may etch the layer 22a, while, when the active layer 18 is made of a combination of GaInNAs and GaAs, and the spacer layers, 16 and 20, are made of GaAs, AlGaAs, or GaInAsP, the phosphoric acid may etch this active layer easily. The intermediate layer 40 is preferably made of GaInP or AlGaInP, because this intermediate layer 40, in this case, becomes an etching stopper layer for the etching of the lower spacer layer 16 made of GaAs, AlGaAs, or GaInAsP, which enhances, as mentioned above, the homogeneity and the reproducibility of the device 50a. Subsequently, processes same as those shown in FIGS. 10B and 10C complete the optical device 50a.

When two spacer layers, 16 and 20, and the layer 22a are made of GaInP or AlGaInP, the intermediate layer 40 may be made of GaAs, AlGaAs or GaInAsP. In this case, a solution containing hydrochloric acid (HCl) may be applicable to the etching of two spacer layers, 16 and 20, and the layer 22a. When the active layer 18 is made of the combination of GaInNAs and GaAs, a solution containing phosphoric acid may be applicable to the etching of the active layer 18. The intermediate layer 40 becomes an etching stopper layer for the etching of the lower spacer layer 16, which enhances, as mentioned earlier, the homogeneity and the reproducibility of the device 50a. It is particularly preferable to apply the intermediate layer 40 when the topmost first DBR structure 14 does not show any etching stopper function.

### Sixth Embodiment

FIG. 13 schematically illustrates a cross section of an optical device according to the sixth embodiment of the invention. The optical device 50b shown in FIG. 13 provide, in addition to the configuration of the prior device 50, an intermediate layer 42 provided between only the lower spacer layer 56 and the first DBR structure 14. Between the current blocking layer 54 and the first DBR structure 14 is not provided with any intermediate layer 42 in this embodiment. This optical device 50b shows the same functions and the same results with those devices according to embodiments already explained.

Next, a method to produce the device 50b will be described.

First, similar to the manufacturing method for the device 50a, after forming the dielectric mask 34 on the layer 22a, which is illustrated in FIGS. 4A and 4B, the process etches the layers, 16 to 22a, to form the mesa, as shown in FIG. 10A. Subsequently, the intermediate layer 40 is etched with a solution containing hydrochloric acid (HCl) when the intermediate layer 40 is made of GaInP or AlGaInP. In this case, the etching rate for the intermediate layer 40 is larger than that of the topmost layer of the first DBR structure 14, which may include GaAs, such that the first DBR structure may perform the etching stopper layer. The topmost layer of the first DBR structure 14 is preferably made of material not containing aluminum (Al), that is, the topmost layer of the first DBR structure 14 is preferably GaAs not AlAs, because, when the topmost layer is AlAs, the etching exposes the AlAs layer beneath the lower spacer layer 16 and the aluminum contained therein is easily oxidized to cause a lot of defects to make it hard to re-grow the semiconductor layer on this AlAs layer. When the GaAs is the topmost layer of the first DBR structure 14, the GaAs may perform the function of the etch-stopper layer for the etchant containing hydrochloric acid, which results in the good homogeneity and the good reproducibility with respect to the mesa shape. Accordingly, the dimensions of the mesa including the current injection layer 22, two spacer layers, 60 and 56, the active layer 58 and the intermediate layer 42 show the good homogeneity and the good reproducibility, so does the optical device 50b.

The optical device 50b shown in FIG. 13 provides the intermediate layer 42 only between the lower spacer layer 56 and the first DBR structure 14; accordingly, the performance of the device 50b may be improved by adjusting the conditions of the intermediate layer 42. For instance, the intermediate layer 42 is made of material with a refractive index higher than that of the current blocking layer 54; the layer configuration may strengthen the optical confinement into the mesa portion. Subsequently, similar processes illustrated in FIGS. 10B and 10C may complete the optical device 50b with the surface emitting type.

When the optical devices according to embodiments mentioned above provide the second DBR structure 28 with the second conduction type, the device may provide the upper electrode 32 on the second DBR structure 28 as long as the electrode has a plane shape not to interrupt the light from the active layer. In this configuration, the current is injected in the active layer through the second DBT structure 28.

While the preferred embodiments of the present invention have been described in detail above, many changes to these embodiments may be made without departing from the true scope and teachings of the present invention. For instance, the optical device mentioned above may be, in addition to the VCSEL, an optical modulator, an optical amplifier or an optical switch like the same. As mentioned, the device may provide the upper electrode 32 on the second DBR structure 28. The current confinement structure 23 may be put between the active layer 18 and the first DBR structure 14 in optical devices according to the first to third embodiments, while, the current injection layer 22 is put between the active layer 58 and the first DBR structure 14 in the optical devices according to the fourth to sixth embodiments. Moreover, the two spacer layers in each optical device may be removed. The present invention, therefore, is limited only as claimed below and the equivalents thereof.

What is claimed is:

1. A vertical cavity surface emitting laser diode, comprising:
a first DBR structure provided on a GaAs substrate with a first conductivity;
an active layer provided on said first DBR structure;
a second DBR structure provided on said active layer;
a current injection layer provided between said first DBR structure and said second DBR structure, said current injection layer injecting carriers into said active layer; and
a current blocking layer provided between said first DBR structure and said second DBR structure,
wherein said current blocking layer is one of an un-doped GaInP or an un-doped AlGaInP and
wherein said current injection layer is put between said current blocking layer.

2. The laser diode according to claim 1,
wherein said active layer and said current injection layer shape a mesa structure, said current blocking layer horizontally putting said mesa structure therebetween so as to cover sides of said mesa structure, and
wherein said second DBR structure is provided on said mesa structure and said current blocking layer.

3. The laser diode according to claim 2,
further comprising an intermediate layer included in said mesa structure, said current blocking layer covering sides of said intermediate layer.

4. The laser diode according to claim 2,
further comprising an intermediate layer provided on said first DBR structure, said mesa structure and said current blocking layer being provided on said intermediate layer.

5. A method for manufacturing a vertical cavity surface emitting laser diode, comprising steps of:
growing a first DBR structure, an active layer, and a semiconductor layer in this order on a GaAs substrate;
etching said semiconductor layer to form a current injection layer with a mesa structure;
growing current blocking layer on both sides of said mesa of said current injection layer; and
forming a second DBR structure on said current blocking layer and said current injection layer,
wherein said current blocking layer are an un-doped GaInP grown at a temperature between 500 to 600° C., or an un-doped AlGaInP grown at a temperature between 500 to 650° C.

6. The method according to claim 5,
wherein said GaInP or said AlGaInP of said current blocking layer is preferably to be grown at temperature between 500 to 550° C.

7. A method for manufacturing a vertical cavity surface emitting laser diode, comprising steps of:
growing a first DBR structure, an active layer, a current blocking layer in this order on a GaAs substrate with a first conduction type;
diffusing impurities for a second conduction type into said current blocking layer from an opening of a dielectric film formed on said current blocking layer, said impurities converting a portion of said current blocking into a current injection layer with a second conduction type; and
growing a second DBR structure on said current blocking layer and said current injection layer after removing said dielectric film on said current blocking layer,
wherein said current blocking layer is selected from a group of an un-doped GaInP grown at a temperature between 500 to 600° C. and am un-doped AlGaInP grown at a temperature between 500 to 650° C.

8. The method according to claim 7,
wherein said GaInP or said AlGaInP of said current blocking layer is preferably to be grown at temperature between 500 to 550° C.
